(19) United States
(12) Patent Application Publication
(10) Pub. No.: US 2025/0199060 A1
(43) Pub. Date: Jun. 19, 2025

(54) INTERPOSER PACKAGE, MOUNTING METHOD, AND BURN-IN TEST APPARATUS

(71) Applicant: Kioxia Corporation, Tokyo (JP)

(72) Inventors: Masaki YOSHIMURA, Arakawa Tokyo (JP); Yuto NISHIMURA, Yokohama Kanagawa (JP); Wataru MAKINO, Kamakura Kanagawa (JP); Yumiko WATANABE, Yokohama Kanagawa (JP)

(73) Assignee: Kioxia Corporation, Tokyo (JP)

(21) Appl. No.: 18/828,014

(22) Filed: Sep. 9, 2024

(30) Foreign Application Priority Data
Dec. 15, 2023 (JP) 2023-212143

(51) Int. Cl. G01R 31/28

(52) U.S. Cl. CPC G01R 31/2868; G01R 31/2863; G01R 31/2875; G01R 31/2896

(57) ABSTRACT

According to one embodiment, an interposer package disposed between a burn-in board and a test device package, includes: a first substrate having the same or substantially the same coefficient of expansion as a coefficient of expansion of the burn-in board; a second substrate having the same or substantially the same coefficient of expansion as a coefficient of expansion of the test device package; a first sheet contact inserted between the first substrate and the second substrate; and a case configured to seal the first substrate, the second substrate, and the first sheet contact. The first sheet contact is sandwiched between the first substrate and the second substrate, thereby electrically connecting the burn-in board and the test device packages to each other, and the first substrate, the second substrate, and the first sheet contact is sealed with the case applying a predetermined pressure, thereby maintaining the electrical connection.

### CROSS REFERENCE TO RELATED APPLICATIONS

This application is based upon and claims the benefit of priority from prior Japanese Patent Application No. P2023-212143 filed on Dec. 15, 2023, the entire contents of which are incorporated herein by reference.

### FIELD

Embodiments described herein relate generally to an interposer package, a mounting method, and a burn-in test apparatus.

### BACKGROUND

Semiconductor integrated circuits (hereinafter also referred to as the Device Under Test (DUT)), such as semiconductor storage devices, have been subjected to stress tests for suppressing an occurrence of initial failures, reliability tests for verify reliability of products, and the like. Such stress tests include, for example, burn-in (BI) tests and the like, and such reliability tests include, for example, environmental tests, long-term life tests, and the like. In the burn-in tests, for example, a burn-in board (BI board) is used on which DUT(s) is placed. The burn-in tests are conducted in a state of the burn-in boards are housed in a test furnace (hereinafter also referred to as a chamber) provided in a burn-in test apparatus. In addition to the DUT(s), for example, a test device(s) for inspecting the DUT(s) may also be placed on the burn-in board. Such a test device may be directly placed on the burn-in board or may be placed on the burn-in board via, for example, a relaying substrate or the like.

### BRIEF DESCRIPTION OF THE DRAWINGS

FIG. 1 is a block diagram schematically illustrating a schematic configuration example of a burn-in test apparatus according to an embodiment.

FIG. 2A is a schematic diagram illustrating an example in which a BGA package housing a test device is directly disposed on a burn-in board.

FIG. 2B is a schematic diagram illustrating an example in which the BGA package and the burn-in board illustrated in FIG. 2A are affected by a temperature change.

FIG. 3 is a side view diagram schematically illustrating a schematic configuration example of an interposer package according to the embodiment.

FIG. 4 is a side view diagram schematically illustrating a connection example of disposing the interposer package illustrated in FIG. 3 between the BGA package and the burn-in board.

FIG. 5A is a side view diagram schematically illustrating an example of a connection portion when the BGA package is mounted on the interposer package.

FIG. 5B is a top view diagram schematically illustrating the connection portion in the interposer package side illustrated in FIG. 5A.

FIG. 6A is a side view diagram schematically illustrating an example of the connection portion after the BGA package illustrated in FIG. 5A is mounted on the interposer package.

FIG. 6B is a side view diagram schematically illustrating an example of a connection portion after an LGA package is mounted on the interposer package.

FIG. 7A is a side view diagram schematically illustrating an example of a connection portion when the interposer package is mounted on the burn-in board.

FIG. 7B is a side view diagram schematically illustrating an example of the connection portion after the interposer package illustrated in FIG. 7A is mounted on the burn-in board.

FIG. 8A illustrates an example of a stacked structure constituting an interposer package according to the embodiment, which is a side view diagram schematically illustrating an example of a thickness of the stacked structure.

FIG. 8B is a side view diagram schematically illustrating an example of a thickness of the stacked structure after the stacked structure illustrated in FIG. 8A is housed in a case.

FIG. 9A is a side view diagram schematically illustrating an example of a gap portion provided in a case of an interposer package according to the embodiment.

FIG. 9B is a side view diagram schematically illustrating an aspect in which a substrate expands due to a temperature change in the case illustrated in FIG. 9A.

FIG. 10A illustrated an example of a stacked structure constituting the interposer package according to the embodiment, which is a side view diagram schematically illustrating an electrical connection relationship in the stacked structure.

FIG. 10B is a side view diagram schematically illustrating an aspect in which a substrate expands due to a temperature change, in the example of the stacked structure illustrated in FIG. 10A.

FIG. 11 is a schematic diagram for explaining an effect of a stress due to a temperature change of a test board in which the interposer package according to the embodiment is mounted between the BGA package and the burn-in board.

FIG. 12 is a side view diagram schematically illustrating a schematic configuration example of a test board using an interposer package according to a modified example 1 of the embodiment.

FIG. 13 is a side view diagram schematically illustrating a schematic configuration example of a test board using an interposer package according to a modified example 2 of the embodiment.

FIG. 14 is a flow chart schematically illustrating an example of a mounting method of the test board using the interposer package according to the embodiment.

### DETAILED DESCRIPTION

Next, certain embodiments will now be explained with reference to drawings. In the description of the following specification or drawings to be explained, the identical or similar reference sign is attached to the identical or similar part. However, the drawings are merely schematic. Moreover, the embodiments described hereinafter merely exemplify a device and/or a method for materializing the technical idea. The embodiments may be changed without departing from the spirit or scope of claims.

Certain embodiments provide an interposer package, a mounting method, and a burn-in test apparatus, capable of reducing a crack due to a temperature change, and the like, without changing various conditions such as a mounting area of a test device on a substrate.

In general, according to the embodiment, an interposer package mounted between a burn-in board and a test device package mounted on the burn-in board, the interposer package includes: a first substrate having a coefficient of expansion that is the same or substantially the same as a coefficient of expansion of the burn-in board; a second substrate having a coefficient of expansion that is the same or substantially the same as a coefficient of expansion of the test device package; a first sheet contact inserted between the first substrate and the second substrate; and a case configured to seal the first substrate, the second substrate, and the first sheet contact. The first sheet contact is sandwiched between the first substrate and the second substrate, thereby electrically connecting the burn-in board and the test device packages to each other, and the first substrate, the second substrate, and the first sheet contact is sealed with the case applying a predetermined pressure, thereby maintaining the electrical connection.

Hereinafter, interposer packages, mounting methods, and burn-in test apparatuses of the present disclosure will be explained with reference to the drawings.

### (Burn-In Test Apparatus in Embodiments)

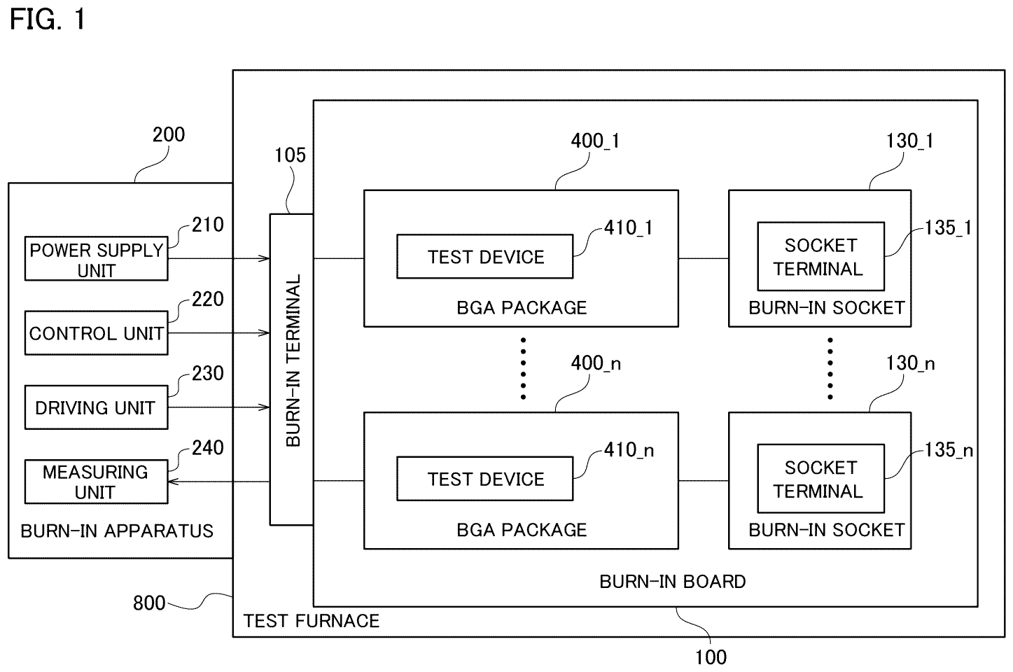

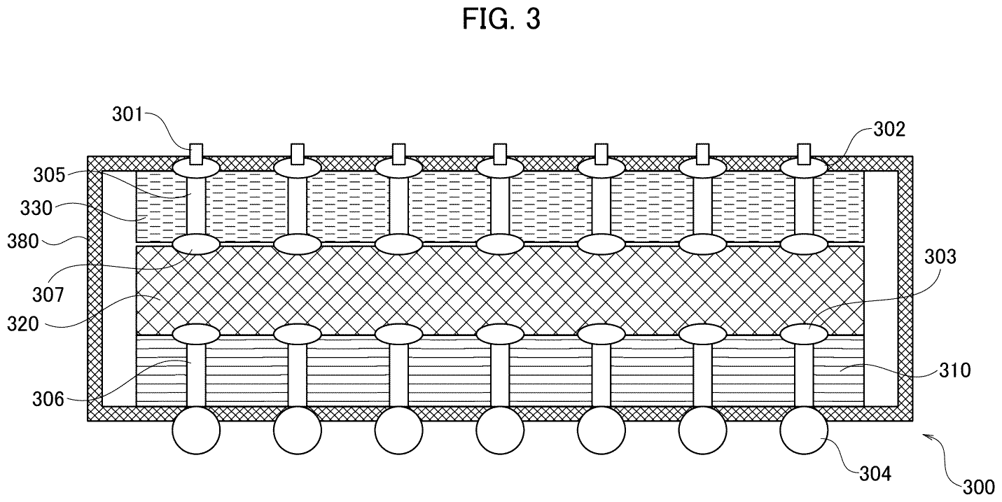

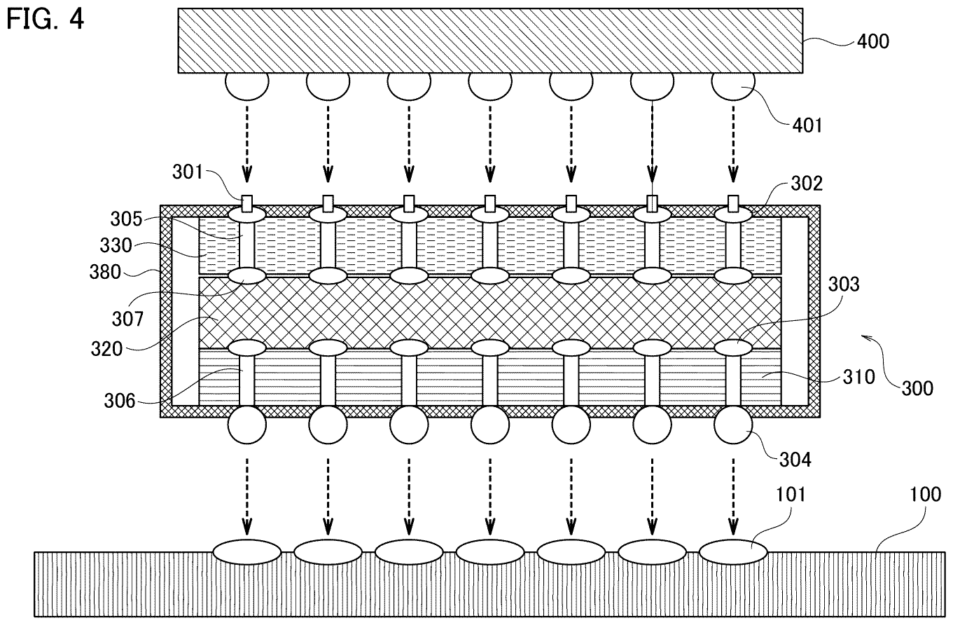

FIG. 1 schematically illustrates a schematic configuration example of a burn-in test apparatus according to an embodiment. The burn-in test apparatus according to the embodiment includes a Ball Grid Array (BGA) package (i.e., a test device package) 400 (400_1, . . . , 400_n), a burn-in board 100, an interposer package 300 (refer to FIGS. 3 and 4), a test furnace 800, and a burn-in apparatus 200. The BGA package 400 (n BGA packages 400_1, . . . , 400_n) houses a test device 410 (n test devices 410_1, . . . , 410_n) configured to conduct a test of a device under test (DUT) (not illustrated). The DUT and the BGA package 400 (400_1, . . . , 400_n) are placed on the burn-in board 100. The interposer package 300 is mounted between the burn-in board 100 and the BGA package 400 (400_1, . . . , 400_n). The test furnace 800 houses the burn-in board 100, the DUT, the interposer package 300, and the BGA package 400 (400_1, . . . , 400_n). The burn-in apparatus 200 conducts, for example, an accelerated test of a temperature-voltage stress, etc. while conducting a function test etc. on the DUT.

The burn-in board 100 is housed in the test furnace 800 as illustrated in FIG. 1 when testing the DUT, and the test is conducted while changing temperatures. When the test of the DUT is completed, the burn-in board 100 is extracted from the test furnace 800.

The DUT is attached to a socket terminal 135 (135_1, . . . , 135_n) provided on the burn-in socket 130 (130_1, . . . , 130_n) mounted on the burn-in board 100. In the example illustrated FIG. 1, one test device 410 is mounted for one DUT, but it is not limited to this example, two or more test devices 410 may be mounted for one DUT, or one test device 410 may be mounted for two or more DUTs.

The burn-in terminal 105 is a terminal for connecting, to the burn-in board 100, the burn-in apparatus 200 capable of supplying power to the burn-in board 100 and controlling the SoC.

The test device 410 (410_1, . . . , 410_n) is a device capable of conducting electrical inspections, such as measurement of electrical characteristics of the DUT connected to each thereof. The burn-in apparatus 200 is capable of supplying power to the burn-in board 100 and controlling the test device 410 mounted on the burn-in board 100.

As the test device package used in the burn-in test apparatus according to the embodiment, for example, a Pin Grid Array (PGA) package, a Land Grid Array (LGA) package, or the like can also be applied, in addition to the BGA package 400 as illustrated in FIG. 1.

Test items for the DUT include an electrical conductivity test, a DC test, a functional test, an AC test, a SCAN test (structural test), a power supply-related test, and the like. If the DUT is a NAND flash memory, cell tests of the NAND memory include: a Pass/Fail test, such as SLC (1 bit/cell), MLC (2 bits/cell), TLC (3 bits/cell), and QLC (4 bits/cell); a test acceptable of a certain error as an error bit test; a fail bit count test exceeding an ECC correction capability required for the cell test as a fail bit count test; an Okay/No-Good determination test of tPROG criteria as a tPROG criteria test, and the like.

As illustrated in FIG. 1, the burn-in apparatus 200 includes a power supply unit 210, a control unit 220, a driving unit 230, and a measuring unit 240. The control unit 220 executes control of each unit in burn-in apparatus 200, i.e., the power supply unit 210, the driving unit 230, the measuring unit 240, and the like, and also executes control of the burn-in board 100 side through the burn-in terminal 105. The power supply unit 210 supplies power to the DUT inserted into the socket terminal 135 (135_1, . . . , 135_n) on the burn-in board 100 and the test device 410 (410_1, . . . , 410_n) on the burn-in board 100, during the burn-in test. The driving unit 230 is configured to drive the test device 410 mounted on the burn-in board 100, during the burn-in test. The measuring unit 240 compares an input voltage with a threshold value of high/low level with respect to the DUT, during the burn-in test.

Incidentally, a burn-in test has been widely conducted as a shipping test for semiconductor integrated circuits such as semiconductor storage devices, in which the test is conducted while applying a stress to DUTs at high or low temperatures. In the burn-in board 100 used in the burn-in test, in order to reduce test costs, it is necessary to increase the number of sockets (e.g., burn-in sockets 130) which can be mounted on the burn-in board 100 to increase the number of DUTs which can be simultaneously measured. In recent years, in order to conduct tests that require signal quality, such as interface testing, in the burn-in apparatus, it has also been configured so that the test device 410 is mounted at a position that is physically closer to the DUT (i.e., to the burn-in socket 130) on the burn-in board 100. Therefore, an arrangement density of the DUTs and the test devices 410 on the burn-in board 100 has become higher.

In particular, when there is a difference in a coefficient of thermal expansion (CTE) (hereinafter simply referred to as a coefficient of expansion) between the BGA package 400 and the burn-in board 100, a stress may be applied to the BGA package 400 and the burn-in board 100 due to a temperature change during the burn-in test.

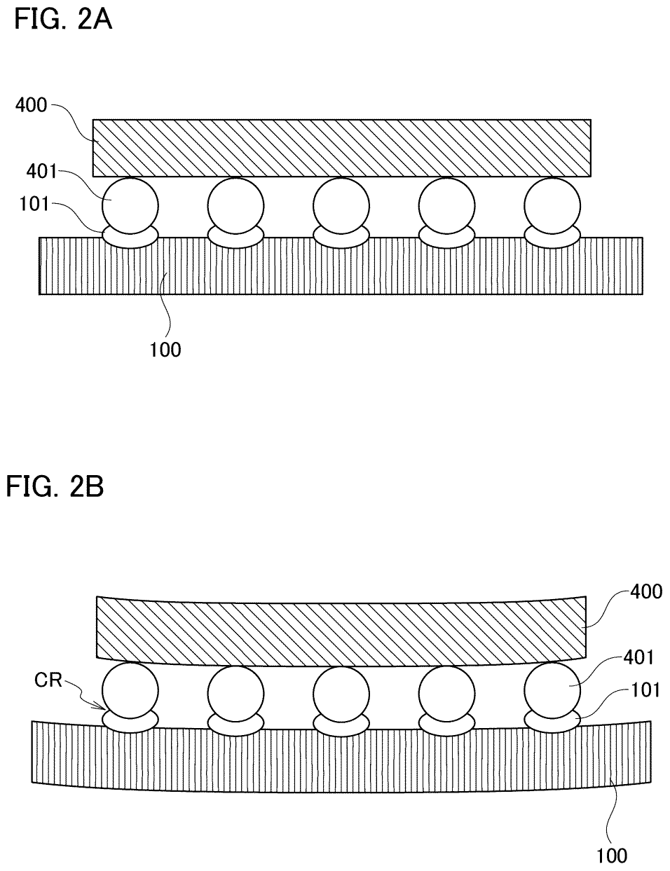

FIG. 2A illustrates an example in which a BGA package 400 housing a test device 410 is directly disposed on a burn-in board 100. FIG. 2B illustrates an example in which the BGA package 400 and the burn-in board 100 illustrated in FIG. 2A are affected by a temperature change. As illustrated in FIG. 2B, when a stress is applied to the BGA package 400 and the burn-in board 100 due to a temperature change during the burn-in test, breaks such as cracks may occur in a BGA(s) 401 bonded to an electrode pad(s) 101 provided on the burn-in board 100.

In particular, when the BGA 401 and the electrode pad 101 are bonded to each other by soldering, the BGA 401 and the electrode pad 101 are alloyed. Therefore, such a crack occurs in many cases near the bonding portion between the electrode pad 101 and the BGA 401 (e.g., near the arrow CR illustrated in FIG. 2B), but may also occur in other locations as well. Moreover, as the number of years of operation increases, such cracks become more likely to occur due to a stress migration or the like. When the BGA 401 (or the electrode pad 101) cracks, an electrical connection between the BGA package 400 and the burn-in board 100 is broken, causing a problem that the burn-in test cannot be correctly conducted.

In order to avoid such a crack occurring in the BGA 401 due to the temperature cycle stress, it is effective to use a sheet contact that connects the BGA 401 and the burn-in board 100 without welding. The sheet contact is formed by arranging extremely small conductors on an insulating sheet to form a narrow path on front and back surfaces of the sheet. A lower end of the conductor (e.g., electrode) of the sheet contact is bonded to each electrode pad 101 of the burn-in board 100, and each BGA 401 of the BGA package 400 is place on an upper end of the conductor (e.g., electrode) of the sheet contact and pressed in an up-and-down direction to make contact, thereby electrically connecting the BGA package 400 and the burn-in board 100 to each other.

However, in order to maintain a stable and continuous electrical connection therebetween, it is necessary to continuously apply a constant pushing pressure to the burn-in board 100 from an upper surface of the BGA package 400 using a socket for mounting the BGA package 400 or the like. Moreover, the use of such sockets is also necessary to ensure positional accuracy of the sheet contact.

However, in order to mount the BGA package 400 using such a sheet contact and socket, a screw hole(s) for fixing the socket(s), a holding mechanism (e.g., a holding latch), or the like are required. Accordingly, a mounting area of the BGA package 400 increases, and therefore the number of the BGA packages 400 and the DUTs which can be mounted on the burn-in board 100 decreases, leading to decrease in the number of simultaneous measurements.

### (Interposer Package According to Embodiments)

FIG. 3 schematically illustrates a schematic configuration example of an interposer package 300 according to the embodiment. FIG. 4 schematically illustrates a connection example when the interposer package 300 illustrated in FIG. 3 is disposed between the burn-in board 100 and the BGA package 400.

As illustrated in FIGS. 3 and 4, the interposer package 300 is a relaying substrate mounted between the burn-in board 100 and the BGA package (e.g., a test device package) 400 mounted on the burn-in board. The interposer package 300 according to the embodiment can be used in the burn-in test apparatus illustrated in FIG. 1.

The interposer package 300 includes: a first substrate 310 having a coefficient of expansion that is the same or substantially the same as a coefficient of expansion of a burn-in board 100; a second substrate 330 having a coefficient of expansion that is the same or substantially the same as a coefficient of expansion of a BGA package 400; a first sheet contact 320 inserted between the first substrate 310 and the second substrate 330; and a hard case 380 configured to seal the first substrate 310, the second substrate 330, and the first sheet contact 320. In the interposer package 300, the first sheet contact 320 is sandwiched between the first substrate 310 and the second substrate 330, electrically connecting the burn-in board 100 and the BGA packages 400 to each other; and the first substrate 310, the second substrate 330, and the first sheet contact 320 are sealed with the case 380 applying a predetermined pressure, thereby maintaining the electrical connection between the burn-in board 100 and the BGA package 400.

As illustrated in FIGS. 3 and 4, a through-VIA electrode(s) 306 is disposed inside the first substrate 310. The through-VIA electrode 306 is connected to an electrode pad 303 formed on a surface of the first sheet contact 320 side of the first substrate 310 and a BGA 304 formed on a surface of the burn-in board 100 side of the first substrate 310. Moreover, a through-VIA electrode(s) 305 is disposed inside the second substrate 330. The through-VIA electrode 305 is connected to an electrode pad 307 formed on a surface of the first sheet contact 320 side of the second substrate 330 and a plug pin 301 and an electrode pad 302 formed on a surface of the BGA package 400 side of the first substrate 310.

The through-VIA electrodes 306 are formed in the first substrate 310 so as to pass through a substrate surface and a substrate back surface thereof, for example, and an insulating substrate etc. which insulate each electrode can be used. The through-VIA electrodes 305 are formed in the second substrate 330 so as to pass through a substrate surface and a substrate back surface thereof, for example, and an insulating substrate etc. which insulate each electrode can be used. For example, a Flame Retardant Type 4 (FR-4), an epoxy resin, glass fiber, a stacked body of copper foil, or the like can be used for the first substrate 310. For example, a thin piece of pelletized silicon wafer to which a mold resin is added can be used for the second substrate 330.

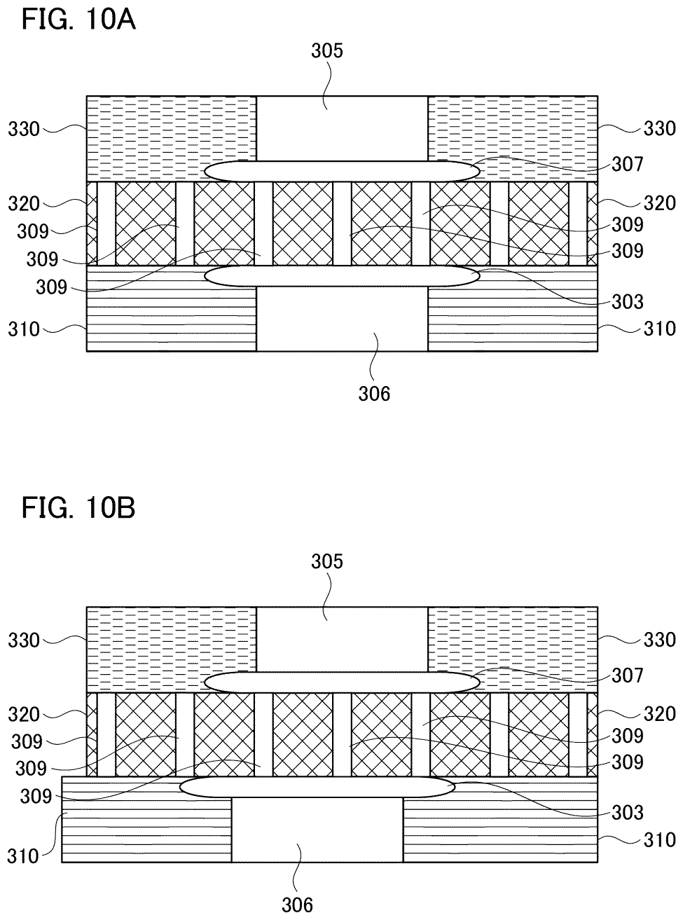

The first sheet contact 320 has a large number of electrodes 309 (refer to FIGS. 10A and 10B) formed of extremely small conductors arranged inside an insulating sheet thereof. The electrode(s) 309 is connected to the electrode pad 303 and the electrode pad 307. The electrode(s) 309 is connected to the electrode pad 303 and the electrode pad 307 so as to in contact with the electrode pad 303 and the electrode pad 307 without being welded thereto with a solder or the like. The electrode(s) 309 is electrically connected to the through-VIA electrode 306 and the through-VIA electrode 305 respectively via the electrode pad 303 and the electrode pad 307.

Then, as illustrated in FIG. 4, the interposer package 300 is mounted on the burn-in board 100 by arranging and soldering the BGA 304 of the first substrate 310 of the interposer package 300 to the respective electrode pads 101 of the burn-in board 100. Moreover, the BGA package 400 is mounted on the interposer package 300 by arranging the BGA 401 of the BGA package 400 to the plug pins 301 of the interposer package 300 to be soldered to the electrode pad 302. Consequently, the BGA 401 of the BGA package 400 and the electrode pad 101 of the burn-in board 100 are electrically connected to each other through the interposer package 300.

The interposer package 300 includes at least three layers, i.e., the first substrate 310, the first sheet contact 320, and the second substrate 330. The first substrate 310 has a coefficient of expansion that is the same or substantially the same as a coefficient of expansion of the burn-in board 100. The second substrate 330 has a coefficient of expansion that is the same or substantially the same as a coefficient of expansion of the BGA package 400.

Thus, the first substrate 310 and the second substrate 330 is electrically connecting to each other by the first sheet contact 320 in the interposer package 300, without being welded to each other. By using a material having the same or substantially the same coefficient of expansion as the coefficient of expansion of the burn-in board 100 for the first substrate 310, distortion between the burn-in board 100 and the first substrate 310 can be avoided even when the burn-in board 100 expands or contracts due to temperature changes. Moreover, by using a material having the same or substantially the same coefficient of expansion as the coefficient of expansion of the BGA package 400 for the second substrate 330, distortion between the BGA package 400 and the second substrate 330 can be avoided even when the BGA package 400 expands or contracts due to temperature changes.

The term material “a having the same or substantially the same coefficient of expansion as the coefficient of expansion of the burn-in board 100” used herein means “a material having the same or substantially the same coefficient of expansion as the coefficient of expansion of the burn-in board 100” such that a solder crack etc. do not occur between the burn-in board 100 and the first substrate 310 even when the burn-in board 100 and the first substrate 310 expand or contract due to temperature changes. In other words, it means “a material having the same or substantially the same coefficient of expansion as the coefficient of expansion of the burn-in board 100” such that the electrical connection between the burn-in board 100 and the first substrate 310 is not disconnected even when the burn-in board 100 and the first substrate 310 expand or contract due to temperature changes.

The term “a material having the same or substantially the same coefficient of expansion as the coefficient of expansion of the BGA package 400” used herein means “a material having the same or substantially the same coefficient of expansion as the coefficient of expansion of the BGA package 400” such that a solder crack etc. do not occur between the BGA package 400 and the second substrate 330 even when the BGA package 400 and the second substrate 330 expand or contract due to temperature changes. In other words, it means “a material having the same or substantially the same coefficient of expansion as the coefficient of expansion of the BGA package 400” such that the electrical connection between the BGA package 400 and the second substrate 330 is not disconnected even when the BGA package 400 and the second substrate 330 expand or contract due to temperature changes.

A thickness of the hard case 380 is formed smaller than the total of a thickness of the first substrate 310, the second substrate 330, and the first sheet contact 320. Therefore, when the first substrate 310, the second substrate 330, and the first sheet contact 320 are housed in the case 380, a predetermined pressure is applied from the first substrate 310 to the first sheet contact 320 and from the second substrate 330 to the first sheet contact 320. Accordingly, the electrical connection between the burn-in board 100 and the BGA package 400 can be maintained.

By mounting the first substrate 310 on the burn-in board 100, a position of the interposer package 300 can be fixed. Moreover, a position of the BGA package 400 can be fixed by mounting the BGA package 400 on the second substrate 330.

Furthermore, a mounting size (i.e., a size in a direction orthogonal to a thickness direction) of the hard case 380 is set to a size capable of housing the maximum expansion size of the first substrate 310 and the second substrate 330. This allows the mounting size to be set so as to not inhibit expansion and contraction of the first substrate 310 and the second substrate 330 due to the influence of temperature changes.

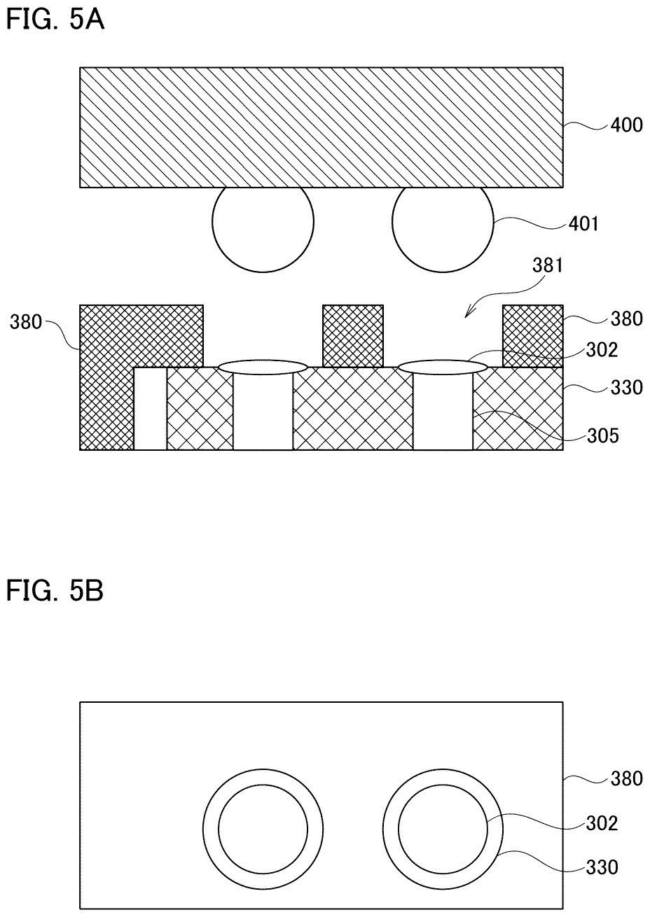

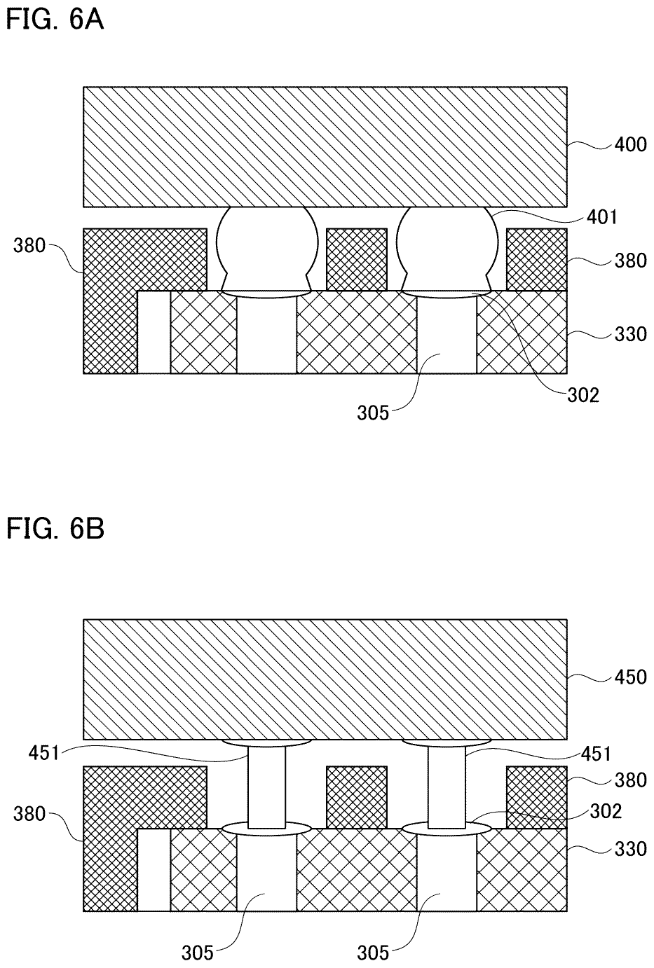

FIG. 5A is a side view diagram schematically illustrating an example of a connection portion when the BGA package 400 is mounted on the interposer package 300. FIG. 5B is a top view diagram schematically illustrating the connection portion on the interposer package 300 side illustrated in FIG. 5A. FIG. 6A is a side view diagram schematically illustrating an example of the connection portion after the BGA package illustrated in FIG. 5A is mounted on the interposer package.

At the connection portion between the BGA package 400 and the interposer package 300, as illustrated in FIG. 5A, the solder ball 401 on the BGA package 400 side is mounted on the electrode pad 302 of the second substrate 330. Moreover, as illustrated in FIG. 5B, an insertion hole 381 is formed in the hard case 380 of the interposer package 300 directly above each electrode pad 302, and the electrode pad 302 of the second substrate 330 is visible (i.e., exposed) from the insertion hole 381. As illustrated in FIG. 6A, each solder ball of the BGA 401 is inserted into the insertion hole 381 and is soldered to be mounted on the electrode pad 302.

As above-described above, a PGA package, an LGA package, and the like can also be applied to the present embodiment, in addition to the BGA package 400. FIG. 6B illustrates an example of a connection portion after mounting an LGA package 450 on the interposer package 300. Since the amount of solder on the LGA package 450 side is small when mounting the LGA package 450, it is possible to mount it by standing a pin 451 on the electrode pad 302 of the second substrate 330 of the interposer package 300 so as to be as a PGA and extending the electrode to the outside of the hard case 380.

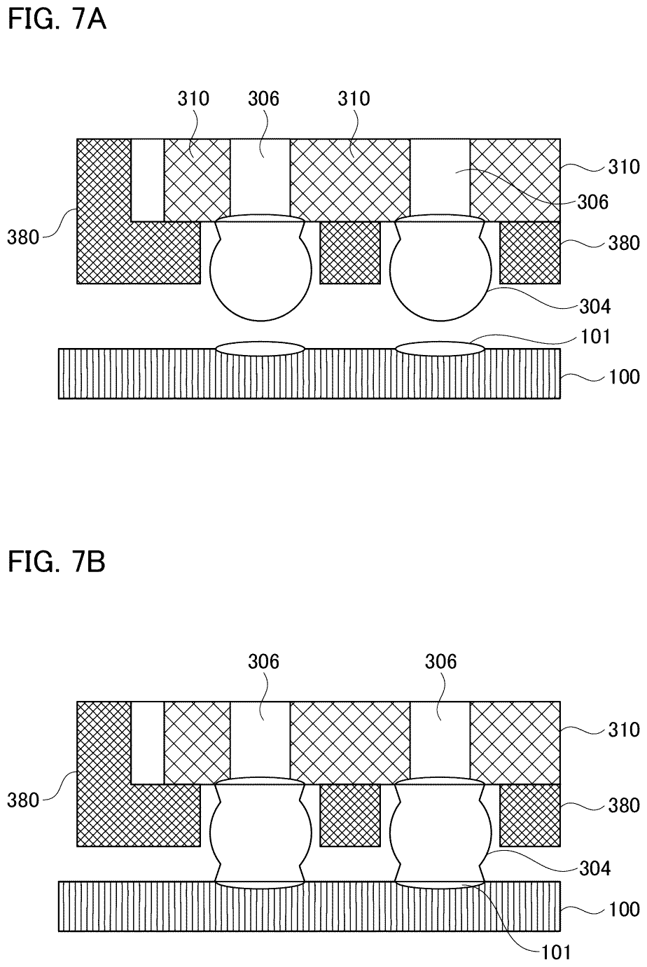

FIG. 7A illustrates an example of a connection portion when mounting the interposer package 300 on the burn-in board 100 viewed from the side surface thereof, and FIG. 7B illustrates an example of the connection portion after the mounting viewed from the side surface thereof.

When the interposer package 300 is mounted on the burn-in board 100, each solder ball of the BGA 304 arranged on the first substrate 310 is placed and soldered to be mounted on each electrode pad 101 on the burn-in board. BGA holes are formed also on a surface of the burn-in board 100 side of the hard case 380 of the interposer package 300, and each solder ball of the BGA 304 is exposed from each BGA hole.

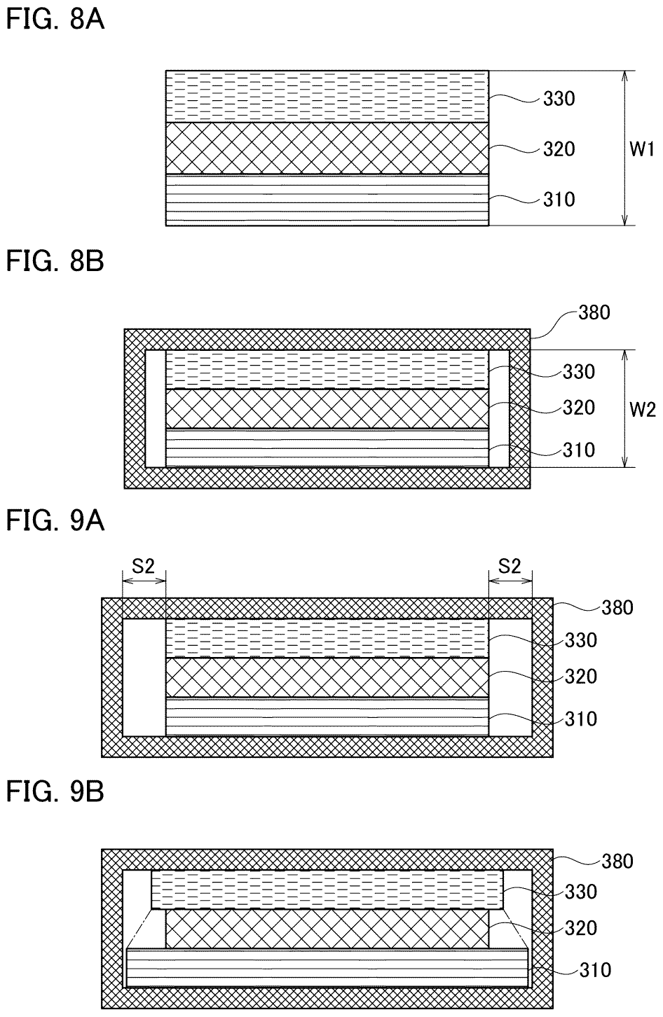

FIG. 8A illustrates an example of a thickness of a stacked structure constituting the interposer package 300 according to the embodiment. FIG. 8B illustrates an example of a thickness of the stacked structure (=a size of the case in a thickness direction) after housing the stacked structure illustrated in FIG. 8A in the case 380. The thickness W2 of the hard case 380 is formed to be smaller than the total thickness W1 of the first substrate 310, the second substrate 330, and the first sheet contact 320. Therefore, when the first substrate 310, the second substrate 330, and the first sheet contact 320 are housed in the case 380, a predetermined pressure is applied from the first substrate 310 to the first sheet contact 320 and from the second substrate 330 to the first sheet contact 320. The predetermined pressure used herein means a pressure applied by a holding mechanism such as a holding latch, which is required when adopting a method of mounting the BGA package 400, for example, using the sheet contact and the socket, without using the case 380. Therefore, it is desirable for the case 380 to be made of a material that is hard enough to withstand a stress caused by the predetermined pressure.

Consequently, the electrical connection between the burn-in board 100 and the BGA package 400 can be maintained. Furthermore, screw holes for fixing, a holding mechanism, and the like become unnecessary by using such a hard case 380. Therefore, an increase in a mounting area of the BGA package 400 can be suppressed, the number of BGA package 400 and DUTs which can be mounted on the burn-in board 100 can be increased, thereby increasing the number of simultaneous measurements.

FIG. 9A illustrates an example of gap portions (S2) provided in the case 380 of the interposer package 300 according to the embodiment. FIG. 9B schematically illustrates an aspect that the first substrate 310 and the second substrate 330 expand due to a temperature change in the interposer package illustrated in FIG. 9A. The mounting size (i.e., a size in a direction orthogonal to a thickness direction) of the case 380 is set to a size capable of housing the maximum expansion size of the first substrate 310 and the second substrate 330. In other words, the mounting size of case 380 is formed to be larger by a difference between a normal size of first substrate 310 and the second substrate 330 before expansion and the maximum size of first substrate 310 and the second substrate 330 after expansion. This allows the mounting size to be set so as to not inhibit expansion and contraction of the first substrate 310 and the second substrate 330 due to the influence of temperature changes.

Assuming that a size of the case 380 is 15 mm square and the first substrate 310 is formed by FR-4, for example, an example of the length of the gap portion S2 is several tens of μm, e.g., approximately 12 μm.

It is to be noted that the first substrate 310 and the second substrate 330 expand and contract also in the up-and-down direction toward the drawing sheet of FIG. 9. However, since there is nothing to contact in the up-and-down direction, expansion or contraction in the up-and-down direction does not need to be taken into consideration.

FIG. 10A schematically illustrates an electrical connection relationship in a stacked structure constituting the interposer package 300 according to the embodiment. FIG. 10B schematically illustrating an aspect in which a substrate expands due to a temperature change, in the example of the stacked structure illustrated in FIG. 10A. The first sheet contact 320 has a large of electrodes 309 made of extremely small conductors disposed passing through inside the sheet of insulation (e.g., at the intersection points of insulation fibers), producing local conductors on front and back surfaces of the sheet. The electrode(s) 309 is connected to the electrode pad 303 and the electrode pad 307 so as to in contact with the electrode pad 303 and the electrode pad 307 without being welded thereto with a solder or the like. That is, the electrical connection therebetween can be established by pressing up and down without a need for precise alignment.

The insulating sheet can be formed of an insulating material such poly-tetrafluoroethylene as (PTFE), polyimide, or liquid crystalline polymer including aramid, for example. The electrode 309 can be, for example, a conductive foil such as Au, or a conductive pin.

The electrode(s) 309 is electrically connected to the through-VIA electrode 306 and the through-VIA electrode 305 respectively via the electrode pad 303 and the electrode pad 307. Such an interposer package 300 is connected and inserted between the burn-in board 100 and the BGA package 400, and thereby the BGA 401 of the BGA package 400 and the electrode pad 101 of the burn-in board 100 are electrically connected to each other through the interposer package 300.

As illustrated in FIGS. 10A and 10B, the electrode 309 in the first sheet contact 320 has an extremely small size compared with the electrode pad 303 and the electrode pad 307. Therefore, when one electrode pad 303 and one electrode pad 307 are electrically connected to each other, a ratio of the number of the electrode pad 303:the electrode 309:the electrode pad 307 is 1:m:1 (where m is an integer greater than or equal to 2). In the examples of FIGS. 10A and 10B, m=3. Therefore, as illustrated in FIG. 10B, even when the first substrate 310 thermally expands to rightward toward the drawing sheet of FIG. 10B, an effect of a position misalignment due to thermal expansion can be absorbed, and the electrical connection between the burn-in board 100 and the BGA package 400 can be maintained.

Moreover, since a position alignment between the first substrate 310 and second substrate 330 and the first sheet contact 320 may be relatively rough, there is no need to give special consideration to the coefficient of expansion of the first sheet contact 320 due to the effect of temperature changes.

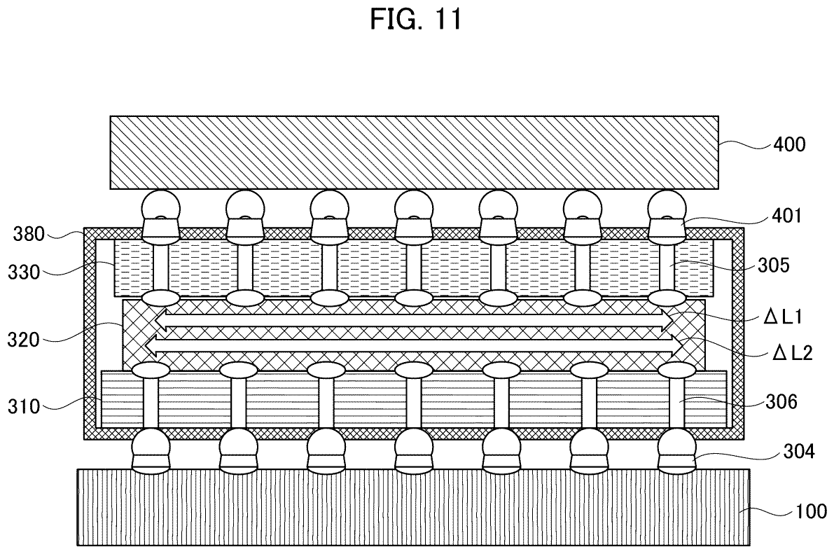

FIG. 11 schematically illustrates an effect of a stress due to a temperature change in which the interposer package 300 according to the embodiment is mounted between the BGA package 400 and the burn-in board 100. In FIG. 11, ΔL2 denotes the amount of expansion on the burn-in board 100 side, and ΔL1 denotes the amount of expansion on the BGA package 400 side. It is illustrated that the stress due to temperature changes can be reduced even when the burn-in board 100 and the interposer package 300 are soldered and fused-bonded and the BGA package 400 and the interposer package 300 are soldered and fused-bonded.

### (Modified Example 1 of Interposer Package)

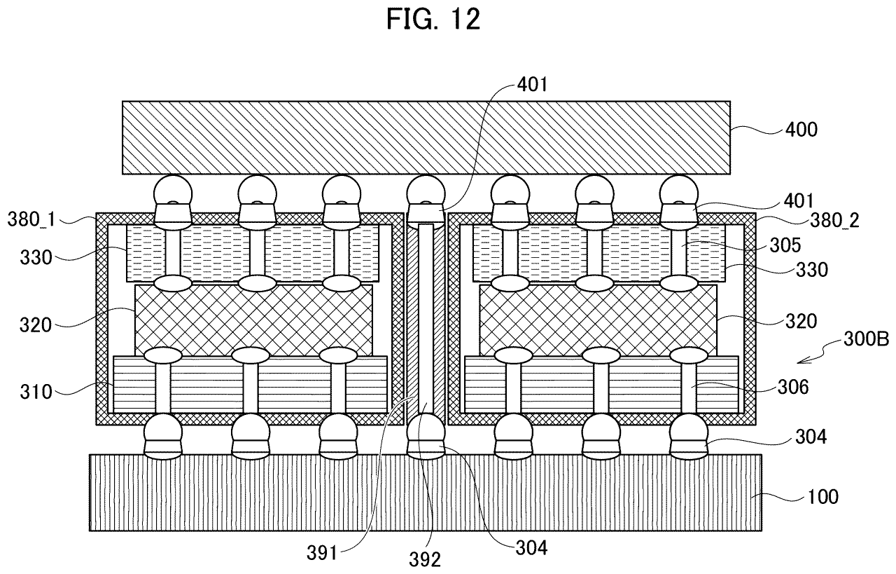

FIG. 12 schematically illustrating a schematic configuration example of a test board using an interposer package 300B according to a modified example 1 of the embodiment. As illustrated in FIG. 12, the interposer package 300B of the modified example 1 includes a through electrode 392 directly connecting one BGA 401 and one BGA 304 at a center portion. A side surface of the through electrode 392 is covered with an insulating resin layer 391. The first substrate 310, the second substrate 330, and the first sheet contact 320 are housed to be divided in two cases 380_1 and 380_2.

The arrangement and bonding method of the burn-in board 100 and BGA package 400 with the interposer package 300B in the modified example 1 are the same as the arrangement and bonding method thereof with the interposer package 300.

By configuring in this way, position misalignment between the burn-in board 100 and the BGA package 400 can be suppressed even when there is a large change in temperature or even when there is a large difference in the coefficient of expansion between the first substrate 310 and the second substrate 330.

The number and arrangement location of the through electrode 392 are not limited to the example illustrated in FIG. 12, and two or more through electrodes 392 may be arranged, or the through electrode may be arranged in a location other than the center portion.

### (Modified Example 2 of Interposer Package)

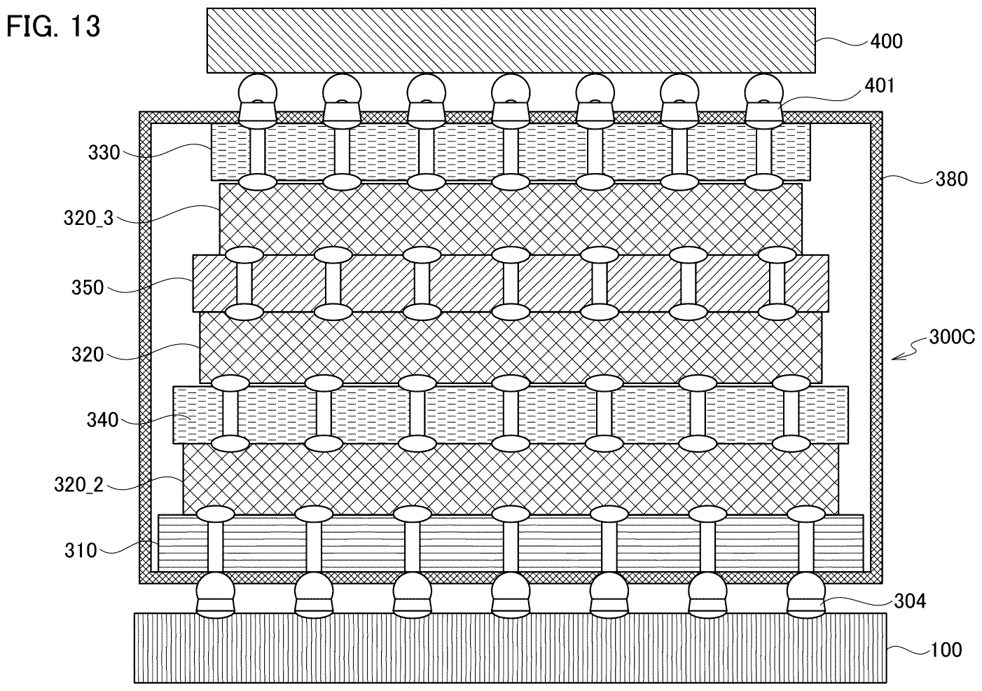

FIG. 13 schematically illustrating a schematic configuration example of a test board using an interposer package 300C according to a modified example 2 of the embodiment. As illustrated in FIG. 13, in the interposer package 300C of the modified example 2, two substrates, i.e., a third substrate 340, and a fourth substrate 350 are inserted between the first substrate 310 and the second substrate 330. The third substrate 340 is inserted between the first substrate 310 and the first sheet contact 320. The fourth substrate 350 is inserted between the second substrate 330 and the first sheet contact 320. Further, a second sheet contact 320_2 is inserted between the first substrate 310 and the third substrate 340. Furthermore, a third sheet contact 320_3 is inserted between the second substrate 330 and the fourth substrate 350.

The second sheet contact 320_2 and the third sheet contact 320_3 may have the same material, structure, and size (e.g., thickness) as the first sheet contact 320.

FIG. 13 illustrates an example where the coefficient of expansion of the burn-in board 100 is larger than the coefficient of expansion of the BGA package 400. As in the example of the interposer package 300 in the embodiment, the first substrate 310 has the same or substantially the same coefficient of expansion as the coefficient of expansion coefficient of expansion of the burn-in board 100, and the second substrate 330 has the same or substantially the same coefficient of expansion as the coefficient of expansion of BGA package 400. In contrast, the third substrate 340 has a coefficient of expansion smaller than the coefficient of expansion of the burn-in board 100 (i.e., the coefficient of expansion of the first substrate 310) and larger than a coefficient of expansion of the fourth substrate 350. Moreover, the fourth substrate 350 has a coefficient of expansion smaller than the coefficient of expansion of the second substrate 330 and larger than the coefficient of expansion of the BGA package 400 (i.e., the coefficient of expansion of the second substrate 330).

Therefore, the coefficients of expansion of the burn-in board 100, the first substrate 310, the third substrate 340, the fourth substrate 350, the second substrate 330, and the BGA package 400 have the following relationship: burn-in board 100≈(almost equal to) first substrate 310>third substrate 340>fourth substrate 350>second substrate 330≈(almost equal to) BGA package 400.

Thus, by inserting the third substrate 340 and the fourth substrate 350 between the first substrate 310 and the second substrate 330, even when a difference between the coefficient of expansion of the burn-in board 100 and the coefficient of expansion of the BGA package 400 is large, distortion due to temperature changes can be absorbed, and the electrical connection between the burn-in board 100 and the BGA package 400 can be maintained.

The relationship between the coefficients of expansion of the substrates is not limited to such an example. For example, when the coefficient of expansion of the burn-in board 100 is smaller than the coefficient of expansion of BGA package 400, the coefficients of expansion of the burn-in board 100, the first substrate 310, the third substrate 340, the fourth substrate 350, the second substrate 330, and the BGA package 400 have the following relationship: burn-in board 100≈(almost equal to) first substrate 310<third substrate 340<fourth substrate 350<second substrate 330≈(almost equal to) BGA package 400.

Furthermore, the number of substrates inserted between the first substrate 310 and the second substrate 330 is not limited to two, but may be three or more. However, the sheet contact is inserted between the substrates.

Furthermore, a structure in which the interposer package 300B of the modified example 1 and the interposer package 300C of the modified example 2 are combined may also be used.

### (Mounting Method According to Embodiments)

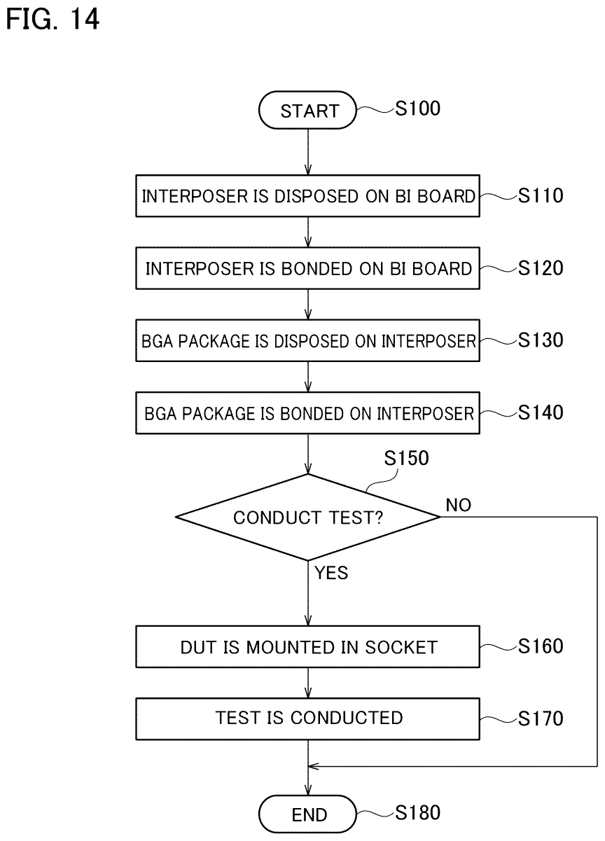

FIG. 14 is a flow chart schematically illustrating an example of a mounting method of a test board using the interposer package 300 according to the embodiment.

It is to be noted that processing operations of the mounting method according to the embodiment described below can also be described in a computer program as instructions to be executed by computers. The computer program is stored in, for example, a non-transitory computer readable medium and is used for the burn-in test apparatus according to the embodiment, unillustrated DUT insertion and removal apparatus, and the like.

In Step S100, the mounting method of the test board using the interposer package 300 is started.

In Step S110, the BGA 304 of the first substrate 310 is disposed (positioned) on the respective electrode pads 101 disposed on the burn-in board 100, and in Step S120, the BGA 304 is soldered and fused-bonded to the respective electrode pads 101.

In Step S130, the BGA 401 of the BGA package 400 is disposed (positioned) on the respective plug pins 301 of the interposer package 300, and in Step S140, the BGA 401 is soldered and fused-bonded to the respective plug pins 301.

In this manner, the test board using the interposer package 300 according to the embodiment is formed.

Then, if a burn-in test is conducted (i.e., YES in Step S150), it proceeds to Step S160. In contrast, if the burn-in test is not conducted (i.e., NO in Step S150), the process is terminated (Step S180).

In the case of YES in Step S150, a DUT is mounted on each burn-in socket 130 disposed on the burn-in board 100 in Step S160, and a burn-in test is conducted in Step S170. When the burn-in test in Step S170 is completed, the process is terminated (Step S180).

Although FIG. 14 illustrated an example in which the process of Steps S130 and S140 is executed after the process in Steps S110 and S120, it is not limited to this example. The process in Steps S130 and S140 may be executed in advance, and then the process in Steps S110 and S120 may be executed, or the process in Steps S110 and S120 and the process in Steps S130 and S140 may be executed in parallel.

The mounting method illustrated in FIG. 14 can be similarly applied to the interposer package 300B of the modified example 1 and the interposer package 300C of the modified example 2.

(Effects Produced from Embodiments)

According to the embodiments, the following effects can be obtained.

(1) It is configured to insert the interposer package 300 (or the interposer package 300_2 or interposer package 300_3) between the burn-in board 100 and the BGA package 400 to establish the electrically connection therebetween, and thereby it is possible to suppress distortion of the substrate (e.g., the burn-in board 100) and the BGA package 400 due to changes in test temperature, and occurrence of solder cracks. In other words, since the stress due to the thermal expansion of the burn-in board 100 is not transferred to the BGA package 400 side and the stress due to the thermal expansion on the BGA package 400 side is not transferred to the burn-in board 100 side, a stable electrical connection can be provided without the BGA cracking even when the temperature changes.

(2) In the interposer package 300, the first sheet contact 320 is sandwiched between the first substrate 310 and the second substrate 330, thereby electrically connecting the burn-in board 100 and the BGA packages 400 to each other. Electrical connection can be realized simply by contacting without soldering. Moreover, by sealing the first substrate 310, the second substrate 330, and the first sheet contact 320 in the hard case 380 while applying the predetermined pressure (e.g., the pressure required for a stable conductivity of the sheet contact), the electrical connection between the burn-in board 100 and the BGA package 400 can be maintained.

(3) Moreover, the positions of the interposer package 300 and the BGA package 400 can be fixed with respect to the burn-in board 100 without using a socket or a screw. Therefore, when designing the substrate, it is possible to select a parts arrangement with the same area and shape as when the BGA package 400 is directly mounted, and the substrate size of the burn-in board 100 can be reduced. Namely, it is possible of a stable contact with the same mounting area as the size of the BGA package 400 without affecting wiring restrictions on the burn-in board 100 or the number of sockets mounted. Moreover, it is applicable similarly to already-existing burn-in boards. Furthermore, even for LGA packages in which the ball diameter of BGA is small, soldering and bonding is possible by using the plug pins or the like.

### OTHER EMBODIMENTS

While certain embodiments have been described, these embodiments have been presented by way of example only, and are not intended to limit the scope of the disclosure. Indeed, the novel substrates, apparatuses, and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An interposer package mounted between a test device package mounted on a burn-in board and a burn-in board, the interposer package comprising:
a first substrate having a coefficient of expansion that is the same or substantially the same as a coefficient of expansion of the burn-in board;
a second substrate having a coefficient of expansion that is the same or substantially the same as a coefficient of expansion of the test device package;
a first sheet contact inserted between the first substrate and the second substrate; and
a case configured to seal the first substrate, the second substrate, and the first sheet contact, wherein
the first sheet contact is sandwiched between the first substrate and the second substrate, thereby electrically connecting the burn-in board and the test device packages to each other, and
the first substrate, the second substrate, and the first sheet contact is sealed with the case applying a predetermined pressure, thereby maintaining the electrical connection.

2. The interposer package according to claim 1, further comprising:
a third substrate disposed between the first substrate and the first sheet contact;
a fourth substrate disposed between the second substrate and the first sheet contact;
a second sheet contact disposed between the first substrate and the third substrate; and
a third sheet contact disposed between the second substrate and the fourth substrate, wherein
when the coefficient of expansion of the burn-in board is larger than the coefficient of expansion of the test device package, a coefficient of expansion of the third substrate is smaller than the coefficient of expansion of the first substrate and larger than a coefficient of expansion of the fourth substrate, and the coefficient of expansion of the fourth substrate is larger than the coefficient of expansion of the second substrate and small than the coefficient of expansion of the third substrate, and
when the coefficient of expansion of the test device package is larger than a coefficient of expansion of the burn-in board, the coefficient of expansion of the fourth substrate is smaller than the coefficient of expansion of the second substrate and larger than the coefficient of expansion of the third substrate, and the coefficient of expansion of the third substrate is larger than the coefficient of expansion of the first substrate and smaller than the coefficient of expansion of the fourth substrate.

3. The interposer package according to claim 1, further comprising
at least one through electrode disposed passing through the first substrate, the second substrate, and the first sheet contact, the through electrode having one end welded to the burn-in board and the other end welded to the test device package.

4. The interposer package according to claim 1, wherein
the test device package is a BGA package, and
the first substrate is mounted on the burn-in board with a BGA arranged on the first substrate.

5. The interposer package according to claim 1, wherein
the test device package is an LGA package, and
the first substrate is mounted on the burn-in board with a plug pin arranged on the first substrate.

6. The interposer package according to claim 4, wherein
the BGA package is mounted to a plug pin arranged on the second substrate.

7. The interposer package according to claim 4, wherein
the BGA package is mounted to a pad arranged on the second substrate.

8. A mounting method comprising:
mounting the interposer package according to claim 1 on the burn-in board; and
mounting the test device package on the interposer package.

9. The mounting method according to claim 8, wherein
the test device package is a BGA package, and
when mounting the interposer package on the burn-in board, the first substrate is mounted on the burn-in board with a BGA arranged on the first substrate.

10. The mounting method according to claim 8, wherein
the test device package is an LGA package, and
when mounting the interposer package on the burn-in board, the first substrate is mounted on the burn-in board with a plug pin arranged on the first substrate.

11. The mounting method according to claim 9, wherein
when mounting the BGA package on the interposer package, the BGA package is mounted to a plug pin arranged on the second substrate.

12. The mounting method according to claim 9, wherein
when mounting the BGA package on the interposer package, the BGA package is mounted to a pad arranged on the second substrate.

13. A burn-in test apparatus comprising:
a test device package in which a test device configured to test a device under test is housed;
a burn-in board in which the device under test and the test device package are placed;
the interposer package according to claim 1 mounted between the burn-in board and the test device package;
a test furnace in which the burn-in board, the device under test, the interposer package, and the test device package are housed; and
a test apparatus configured to conduct, for the device under test, an accelerated test of a temperature-voltage stress while conducting a function test.

14. The burn-in test apparatus according to claim 13, further comprising:
a third substrate disposed between the first substrate and the first sheet contact;
a fourth substrate disposed between the second substrate and the first sheet contact;
a second sheet contact disposed between the first substrate and the third substrate; and
a third sheet contact disposed between the second substrate and the fourth substrate, wherein
when the coefficient of expansion of the burn-in board is larger than the coefficient of expansion of the test device package, a coefficient of expansion of the third substrate is smaller than the coefficient of expansion of the first substrate and larger than a coefficient of expansion of the fourth substrate, and the coefficient of expansion of the fourth substrate is larger than the coefficient of expansion of the second substrate and small than the coefficient of expansion of the third substrate, and
when the coefficient of expansion of the test device package is larger than a coefficient of expansion of the burn-in board, the coefficient of expansion of the fourth substrate is smaller than the coefficient of expansion of the second substrate and larger than the coefficient of expansion of the third substrate, and the coefficient of expansion of the third substrate is larger than the coefficient of expansion of the first substrate and smaller than the coefficient of expansion of the fourth substrate.

15. The burn-in test apparatus according to claim 13, wherein
the interposer package further comprising
at least one through electrode disposed passing through the first substrate, the second substrate, and the first sheet contact, the through electrode having one end welded to the burn-in board and the other end welded to the test device package.

16. The burn-in test apparatus according to claim 13, wherein
the test device package is a BGA package, and
in the interposer package, the first substrate is mounted on the burn-in board with a BGA arranged on the first substrate.

17. The burn-in test apparatus according to claim 13, wherein
the test device package is an LGA package, and
in the interposer package, the first substrate is mounted on the burn-in board with a plug pin arranged on the first substrate.

18. The burn-in test apparatus according to claim 16, wherein
in the interposer package, the BGA package is mounted to a plug pin arranged on the second substrate.

19. The burn-in test apparatus according to claim 16, wherein
in the interposer package, the BGA package is mounted to a pad arranged on the second substrate.
